(19) United States
(12) Patent Application Publication
(10) Pub. No.: US 2026/0025991 A1
(43) Pub. Date: Jan. 22, 2026

(54) MICROELECTRONIC DEVICES, MEMORY DEVICES, AND ELECTRONIC SYSTEMS

(71) Applicant: Micron Technology Inc., Boise, ID (US)

(72) Inventors: Aaron S. Yip, Los Gatos, CA (US); Qui V. Nguyen, San Jose, CA (US)

(21) Appl. No.: 19/242,812

(22) Filed: Jun. 18, 2025

Related U.S. Application Data
(60) Provisional application No. 63/672,918, filed on Jul. 18, 2024.

(51) Int. Cl. H10B 41/20; H01L 23/522; H01L 23/528; H10B 41/35; H10B 43/20; H10B 43/35

(52) U.S. Cl. CPC H10B 41/20; H01L 23/5226; H01L 23/5283; H10B 41/35; H10B 43/20; H10B 43/35

(57) ABSTRACT

A microelectronic device may include a plane comprising blocks horizontally extending in parallel in a first direction and horizontally alternating with slot structures in a second direction orthogonal to the first direction. The blocks may include tiers individually including conductive material and insulative material vertically neighboring the conductive material. The device may also include an additional plane horizontally neighboring the plane in the second direction and including additional blocks similar to the blocks. At least one source structure may vertically underlie and horizontally overlap horizontal areas of the plane and the additional plane. A plane separation region may be interposed between the plane and the additional plane in the second direction. The plane separation region may have a horizontal width in the second direction that is less than or equal to a combined horizontal width in the second direction of one of the blocks and two of the slot structures.

### CROSS-REFERENCE TO RELATED APPLICATIONS

This application claims the benefit under 35 U.S.C. § 119(e) of U.S. Provisional Patent Application Ser. No. 63/672,918, filed Jul. 18, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

### BRIEF DESCRIPTION OF THE DRAWINGS

FIG. 1A is a schematic top view of a microelectronic device structure. FIG. 1B is a schematic side view of the microelectronic device structure of FIG. 1A.

FIG. 2A is a schematic top view of a microelectronic device structure, in accordance with some embodiments of the disclosure. FIG. 2B is a schematic side view of the microelectronic device structure of FIG. 2A.

FIG. 3A is a schematic top view of a microelectronic device structure, in accordance with some additional embodiments of the disclosure. FIG. 3B is a schematic side view of the microelectronic device structure of FIG. 3A.

FIG. 4A is a schematic top view of a microelectronic device structure, in accordance with some further embodiments of the disclosure. FIG. 4B is a schematic side view of the microelectronic device structure of FIG. 4A.

FIG. 5 illustrates a partial cutaway perspective view of a portion of a microelectronic device, in accordance with some embodiments of the disclosure.

FIG. 6 is a schematic block diagram of an electronic system, in accordance with some embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms following “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓWy_{O}, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

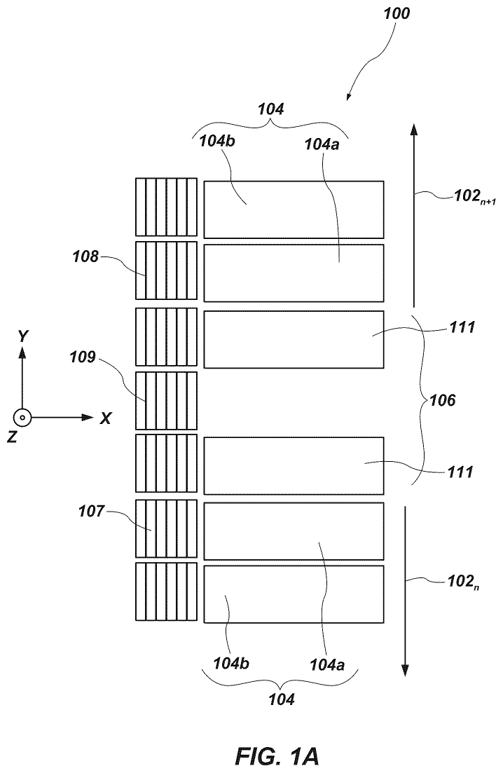

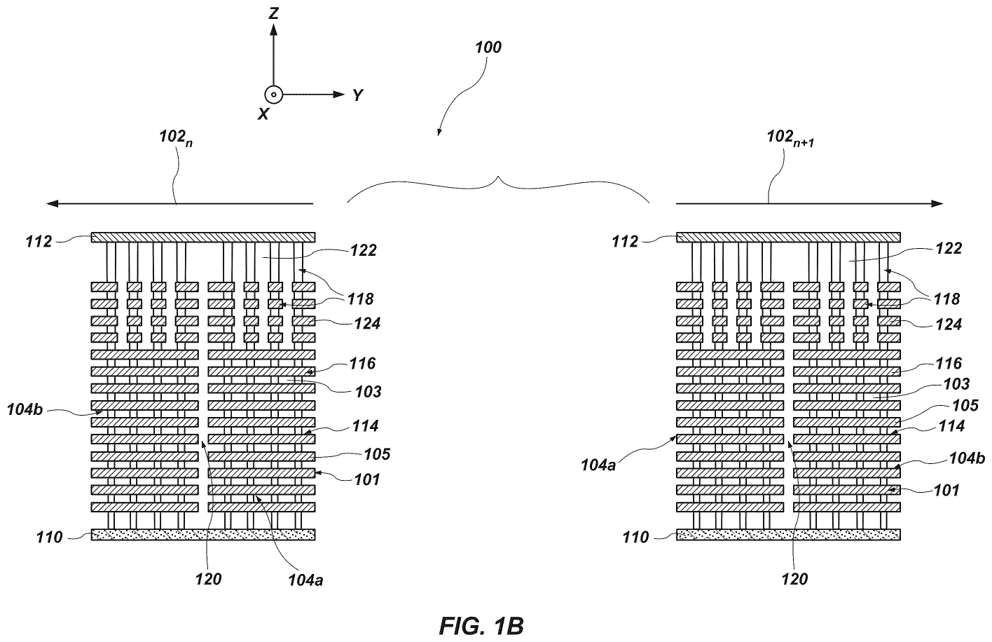

FIG. 1A is a schematic top view of a microelectronic device structure 100 for a microelectronic device (e.g., a memory device, such as a 3D NAND Flash memory device). FIG. 1B is a schematic side view of the microelectronic device structure 100 of FIG. 1A. In FIGS. 1A and 1B, a microelectronic device structure 100 may include a die that is subdivided into a plurality of planes 102. Each of the planes 102 may comprise a plurality of blocks 104, such as at least three or more blocks 104 (such as blocks 104a, 104b, and additional blocks 104 extending in the Y-direction). The blocks 104 may respectively and collectively included in in a memory device, such as a 3D NAND Flash memory device. The blocks 104 may horizontally extend in parallel with one another (e.g., in the X-direction), and may individually include a stack structure 114 including tiers 101 respectively including of insulative material 103 and conductive material 105 vertically neighboring the insulative material 103. Cell pillar structures 118 may be positioned within horizontal areas of the blocks 104 and may vertically extend through the blocks 104. Within an individual block 104, intersections of the cell pillar structures 118 and the conductive material 105 of some of the tiers 101 of the stack structure 114 may define vertically extending (e.g., extending in the Z-direction) strings of memory cells 116 (e.g., metal-oxide-nitride-oxide-semiconductor (MONOS) cells).

Slot structures 120 may horizontally extend in parallel with one another (e.g., in the X-direction), and may horizontally alternate (e.g., in the Y-direction) with the blocks 104. Within an individual plane 102, respective slot structures 120 may be horizontally interposed (e.g., in the Y-direction) between horizontally neighboring blocks 104, such as between blocks 104a and 104b shown in FIGS. 1A and 1B. The slot structures 120 may vertically extend (e.g., in the Z-direction) across substantially an entire vertical height of the blocks 104, and may respectively be formed of and include insulative material.

As shown in FIG. 1B, within an individual block 104, additional slot structures 122 may be formed to vertically extend (e.g., in the Z-direction) an upper group of the tiers 101 of the stack structure 114 thereof. The additional slot structures 122 and may sub-divide the tiers 101 of the upper group to define select gate drain (“SGD”) structures 124 from the conductive material 105 of the tiers 101 of the upper group.

Bit lines 112 (e.g., digit lines, data lines) may be disposed vertically above the blocks 104 of each of the planes 102. Within an individual plane 102, the cell pillar structures 118 (and, hence, the vertically extending strings of memory cells 116) within the blocks 104 may be coupled to a group of the bit lines 112. In addition, within a horizontal area of an individual plane 102, at least one source structure 110 (e.g., a source plate) may be disposed vertically below (e.g., in the Z-direction) the block 104 of the plane 102, and may be coupled to the cell pillar structures 118 (and, hence, the vertically extending strings of memory cells 116) within the blocks 104 of the plane 102.

Referring to FIG. 1A, the blocks 104 may respectively further include at least one staircase structure 108 including steps 107 defined by horizontal ends (e.g., edges) of at least some of the tiers 101 of the stack structure 114 thereof. Risers of the steps 107 may individually have a vertical height (e.g., in the Z-direction) corresponding to a vertical height of an individual tier 101 of the stack structure 114. Treads of the steps 107 may serve contact locations (e.g., interconnect locations) for select gates (e.g., the SGD structures 124, select gate source (SGS) structures) and access lines (e.g., word lines) defined by the conductive material 105 of the tiers 101 of each block 104.

Still referring to FIGS. 1A and 1B, a first plane 102ₙ may include multiple of the blocks 104, including a first block 104a that may be considered an edge block of the first plane 102ₙ, a second block 104b horizontally neighboring (e.g., in the Y-direction) the first block 104a, and one or more additional blocks. In addition, a second plane 102ₙ₊₁ may horizontally neighbor (e.g., in the Y-direction) the first plane 102ₙ and may be separated from the first plane 102ₙ by a plane separation region 106. The second plane 102ₙ₊₁ may also include a first block 104a that may be considered an edge block of the second plane 10ₙ₊₁, a second block 104b horizontally neighboring (e.g., in the Y-direction) the first block 104a, and one or more additional blocks. The microelectronic device structure 100 may also include additional planes 102.

In the plane separation region 106 between the first and second planes 102ₙ, 102ₙ₊₁ of the microelectronic device structure 100, one or more non-functional or “dummy” staircase structures 109 may be provided. The dummy staircase structure 109 may be provided to maintain continuity during fabrication, such as during etching of the staircase structures 108 of the blocks 104.

The plane separation region 106 may exhibit a horizontal dimension (e.g., a width) in the Y-direction that is a multiple of a pitch of the blocks 104. This may be due at least in part to the non-functional staircase structures 109 spanning the plane separation region 106. In some instances, the edge blocks 104a of each of the first and second planes 102ₙ, 102ₙ₊₁ is susceptible to etch effects and etch loading variations due to chemical loading and mechanical stresses. Accordingly, within the plane separation region 106, the microelectronic device structure 100 may include non-functional or “dummy” blocks 111 horizontally neighboring the first and second planes 102ₙ, 102ₙ₊₁ to counteract uneven etch loading in the edge blocks 104a of the first and second planes 102ₙ, 102ₙ₊₁. Accordingly, the plane separation region 106 may exhibit a width equal to a sum of the widths of at least three of the blocks 104, as well as the slot structures 120 horizontally alternating (e.g., in the Y-direction) therewith.

In some embodiments, the plane separation region 106 may be configured to accommodate interconnect structures (e.g., conductive contacts, conductive vias) that vertically extend (e.g., in the Z-direction) through the microelectronic device structure 100. In some embodiments, it is desirable to reduce or eliminate the plane separation region 106 to reduce the size of the die and to further mitigate uneven edge loading at the edge blocks 104a of the first and second planes 102ₙ, 102ₙ₊₁. The reduction or elimination of the plane separation region 106 may enhance processing efficiency and facilitate relatively greater packing density.

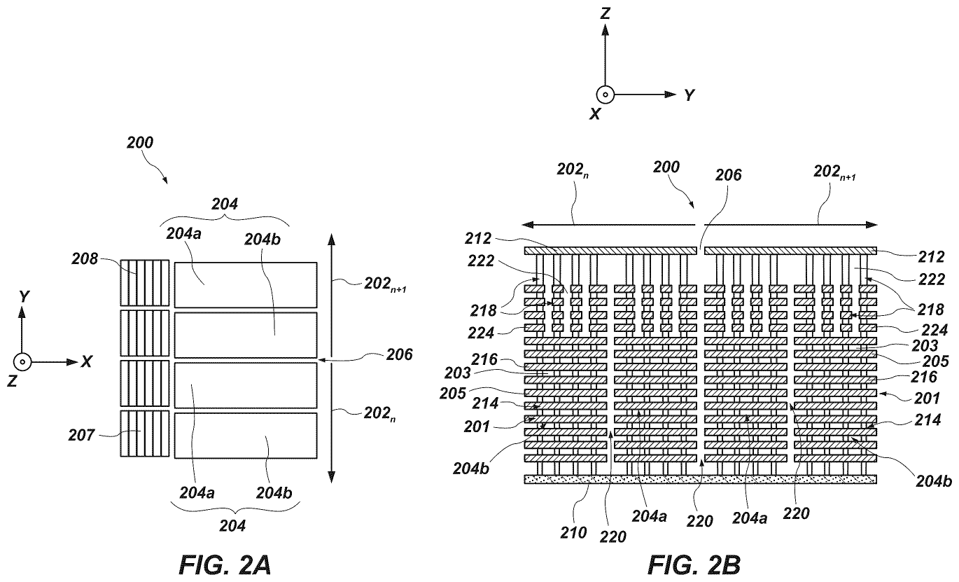

FIG. 2A is a schematic top view of a microelectronic device structure 200 for a microelectronic device (e.g., a memory device, such as a 3D NAND Flash memory device), in accordance with embodiments of the disclosure. FIG. 2B is a schematic side view of the microelectronic device structure 200 of FIG. 2A. In FIGS. 2A and 2B, a microelectronic device structure 200 may include a plurality of planes 202 each including a plurality of blocks 204.

Referring collectively to FIGS. 2A and 2B, the microelectronic device structure 200 includes features (e.g., structures, material, regions, devices) functionally similar to respective features of the microelectronic device structure 100 previously described with reference to FIGS. 1A and 1B. In FIGS. 2A and 2B, and subsequent figures, such features are referred to with reference numerals similar to those for respective features of the microelectronic device structure 100, but incremented by 100. To avoid repetition, not all features shown in FIGS. 2A and 2B (and subsequent figures) are described in detail herein. Rather, unless described otherwise below, a feature designated by a reference numeral that is a 100 increment of the reference numeral of a feature previously described with reference to one or more of FIGS. 1A and 1B will be understood to be substantially similar to and have substantially the same advantages as the previously described feature. As a non-limiting example, in FIGS. 2A and 2B, a first plane 202. (including a first block 204a and a second block 204b thereof) may be substantially similar to the first plane 102ₙ (including the first block 104a and the second block 104b thereof) previously described herein with reference to FIGS. 1A and 1B. As an additional non-limiting example, in FIGS. 2A and 2B, a second plane 202ₙ₊₂ (including a first block 204a and a second block 204b thereof) may be substantially similar to the second plane 102ₙ₊₂ (including the first block 104a and the second block 104b thereof) previously described herein with reference to FIGS. 1A and 1B.

As shown in FIGS. 2A and 2B, the microelectronic device structure 200 includes a relative smaller plane separation region 206 as compared to the plane separation region 106 (FIGS. 1A and 1B) of the microelectronic device structure 100 (FIGS. 1A and 1B). The plane separation region 206 may be horizontally interposed between the first plane 202ₙ and the second plane 202ₙ₊₁, and may be reduced to (e.g., may only include) a single slot structure 220 formed between the first plane 202ₙ and the second plane 202ₙ₊₁. In the microelectronic device structure 200, only one (1) slot structure 220 is horizontally interposed (e.g., in the Y-direction) between the edge block 204a of the first plane 202ₙ and the edge block 204a of the second plane 202ₙ₊₁. For example, the edge block 204a of the first plane 202ₙ is spaced apart from the edge block 204a of the second plane 202ₙ₊₁ by a distance similar to that for the spacing between the edge block 204a of the first plane 202ₙ and the second block 204b of the first plane 202. (e.g., a width of a single slot structure 220). Given that the plane separation region 206 may only include one (1) slot structure 220 within a horizontal area thereof, the microelectronic device structure 200 may be considered to be effectively free of the plane separation region 206 (e.g., the plane separation region 206 may be considered to effectively be absent from the microelectronic device structure 200). The reduced (effectively eliminated) plane separation region 206 may reduce overall die size as compared to the configuration of the microelectronic device structure 100 (FIGS. 1A and 1B), and uneven edge loading at the edge blocks 204a of the first and second planes 202ₙ, 202ₙ₊₁ may be prevented.

As shown in FIG. 2B, the microelectronic device structure 200 further includes a source structure 210 vertically underlying (e.g., in the Z-direction) the blocks 204 of the planes 202 (e.g., the first plane 202ₙ and the second plane 202ₙ₊₁). As shown in FIG. 2B, the source structure 210 may substantially continuously horizontally extend across and between the blocks 104 of multiple planes 102 of the microelectronic device structure 200. For example, the source structure 210 substantially continuously horizontally extend across and between both the first plane 202ₙ and the second plane 202ₙ₊₁.

Because the microelectronic device structure 200 includes a single (e.g., only) source structure 210 vertically underlying and horizontally extending across and between the first and second planes 202ₙ, 202ₙ₊₁, the source structure 210 may be configured to be permanently grounded, such that a read operation is performed as a grounded source read. With the single source structure 210, the microelectronic device structure 200 may not be configured for a biased read operation. For a programming operation for the microelectronic device structure 200 shown in FIGS. 2A and 2B, the operation may be performed as an equivalent operation. For example, a TLC NAND may not be mixed with a QLC NAND. With the single source structures 210 below the two planes 202, an operation where both planes 202 operate independently (e.g., a read operation performed on the first plane 202ₙ and a program operation performed on the second plane 202ₙ₊₁) may not be effectuated during use and operation of a microelectronic device including the microelectronic device structure 200.

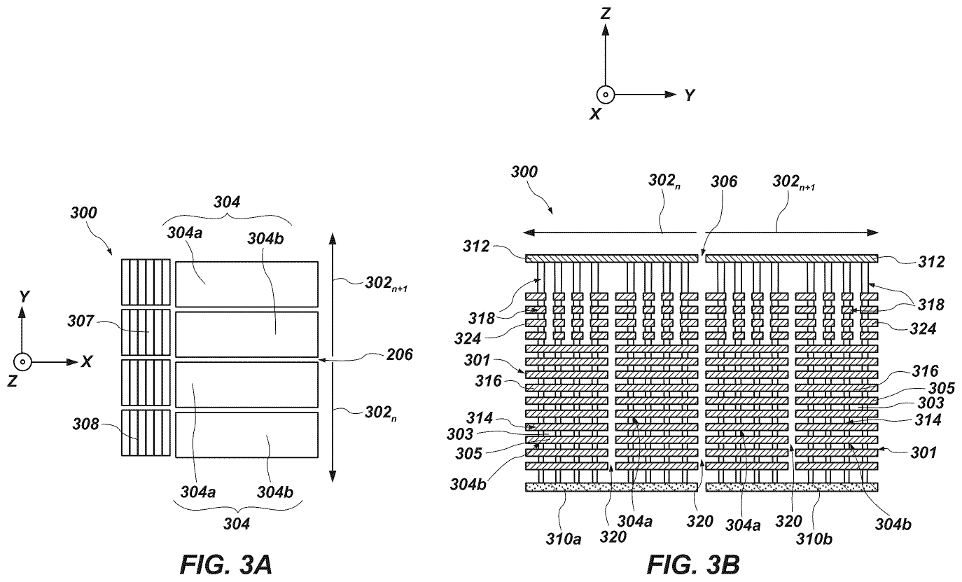

FIG. 3A is a schematic top view of a microelectronic device structure 300 for a microelectronic device (e.g., a memory device, such as a 3D NAND Flash memory device), in accordance with additional embodiments of the disclosure. FIG. 3B is a schematic side view of the microelectronic device structure 300 of FIG. 3A. The microelectronic device structure 300 may include a plurality of planes 302. Each of the planes 302 may include a plurality of blocks 304. As previously described herein, features (e.g., structures, material, regions, devices) of the microelectronic device structure 300 functionally similar to respective features of the microelectronic device structure 100 previously described with reference to FIGS. 1A and 1B are referred to with reference numerals similar to those for the respective features of the microelectronic device structure 100, but incremented by 100.

As shown in FIGS. 3A and 3B, similar to the microelectronic device structure 200 (FIGS. 2A and 2B), the microelectronic device structure 300 includes a reduced plane separation region 306 (e.g., effectively no plane separation region) between the planes 302 (e.g., the first plane 302ₙ and the second plane 302ₙ₊₂) thereof. Similar to the configuration of the microelectronic device structure 200 (FIGS. 2A and 2B), the reduced (effectively eliminated) plane separation region 306 may reduce overall die size as compared to the configuration of the microelectronic device structure 100 (FIGS. 1A and 1B), and uneven edge loading at the edge blocks 304a of the first and second planes 302ₙ, 302ₙ₊₁ may be prevented. However, unlike the microelectronic device structure 200 (FIGS. 2A and 2B), microelectronic device structure 300 does not include only one source structure continuously horizontally extending across and between the first plane 302ₙ and the second plane 302ₙ₊₂ thereof. Instead, the microelectronic device structure 300 includes a first source structure 310a vertically underlying and horizontally extending continuously across the first plane 302ₙ; and a second source structure 310b vertically underlying and horizontally extending continuously across of the second plane 302ₙ₊₁. The first source structure 310a is separate and discrete from the second source structure 310b. The first and second source structures 310a, 310b may be fabricated by forming a single, continuous preliminary source structure, and then partitioning (e.g., cutting) the preliminary source structure horizontally (e.g., in the Y-direction) between the first plane 302ₙ and the second plane 302ₙ₊₁.

With the first source structure 310a vertically under and horizontally extending across the first plane 302ₙ and the separate, second source 310b vertically under and horizontally extending across the second plane 302ₙ₊₁, a read operation may be effectuated as a grounded operation or a source biased operation during use and operation of a microelectronic device including the microelectronic device structure 300. Further, a program operation may be conventionally effectuated. In some examples, during an erase operation or during simultaneous independent operations in different planes 302 (e.g., a read operation performed on the first plane 302ₙ and a program operation performed on the second plane 302ₙ₊₁), the voltage in one of the first source structure 310a or the second source structure 310b may be controlled to prevent dielectric breakdown potential between the first source structure 310a and the second source structure 310b.

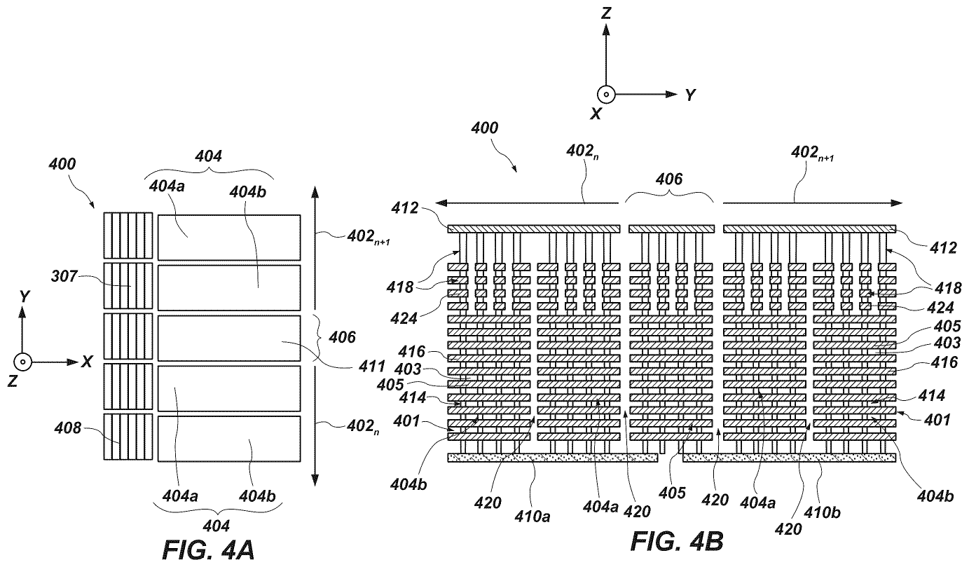

FIG. 4A is a schematic top view of a microelectronic device structure 400 for a microelectronic device (e.g., a memory device, such as a 3D NAND Flash memory device), in accordance with further embodiments of the disclosure. FIG. 4B is a schematic side view of the microelectronic device structure 400 of FIG. 4A. The microelectronic device structure 400 may comprise a plurality of planes 402. As previously described herein, features (e.g., structures, material, regions, devices) of the microelectronic device structure 400 functionally similar to respective features of the microelectronic device structure 100 previously described with reference to FIGS. 1A and 1B are referred to with reference numerals similar to those for the respective features of the microelectronic device structure 100, but incremented by 100.

As shown in FIGS. 4A and 4B, as compared to the microelectronic device structure 100 (FIGS. 1A and 1B), the microelectronic device structure 400 may include plane separation region 406 between the first plane 402ₙ and the second plane 402ₙ₊₂ thereof that is relatively smaller (e.g., in the Y-direction) than the plane separation region 106 between the first plane 102ₙ and the second plane 102ₙ₊₂ previously described herein with reference to FIGS. 1A and 1B. However, the plane separation region 406, may be relatively larger than the plane separation region 206 (FIGS. 2A and 2B) and of microelectronic device structure 200 (FIGS. 2A and 2B) and the plane separation region 306 (FIGS. 3A and 3B) and of microelectronic device structure 300 (FIGS. 3A and 3B). In the microelectronic device structure 400, a single (e.g., only one) non-functional or “dummy” block 411 may be disposed within the plane separation region 406 horizontally interposed between the first plane 402ₙ, and the second plane 402ₙ₊₁. The edge block 404a of the first plane 402ₙ and the edge block 404a of the second plane 402ₙ₊₁ may each horizontally neighbor (e.g., in the Y-direction) the non-functional block 405. The edge block 404a of the first plane 402ₙ may be spaced apart from the non-functional block 405 by a distance substantially similar to that between the edge block 404a of the first plane 402ₙ and the non-functional block 405. Thus, the plane separation region 406 may have a width about equal to the combined width of one of the blocks 404 (e.g., the width of the non-functional block 405) and two of the slot structures 420. In comparison, the width of the plane separation region 106 between the first plane 102ₙ and the second plane 102ₙ₊₂ previously described herein would be about equal to the combined with of three of the blocks 104 and four of the slot structures 120. Thus, even with the single non-functional block 405, the plane separation region 406 may be substantially reduced as compared to the plane separation region 106. In some embodiments, plane separation region 406 has a width, in the Y-direction, less than a combined width in the Y-direction of three of the blocks 404, such as less than or equal to a combined width in the Y-direction of two of the blocks 404. The reduced plane separation region 406 may reduce overall die size as compared to the configuration of the microelectronic device structure 100 (FIGS. 1A and 1B), and uneven edge loading at the edge blocks 404a of the first and second planes 402ₙ, 402ₙ₊₁ may be prevented.

As shown in FIG. 4B, the microelectronic device structure 400 may include a first source structure 410a, and a second source structure 410b discrete and separate from the first source structure 410a. The first source structure 410a may vertically underlie substantially continuously horizontally extend across the first plane 402ₙ, and may partially horizontally extend (e.g., in the Y-direction) into the plane separation region 406. A terminal end of the first source structure 410a may be within a horizontal area of the non-functional block 405 within the plane separation region 406. The second source structure 410b may vertically underlie substantially continuously horizontally extend across the second plane 402ₙ₊₁, and may partially horizontally extend (e.g., in the Y-direction) into the plane separation region 406. A terminal end of the second source structure 410b may be within the horizontal area of the non-functional block 405 within the plane separation region 406. With the single non-functional block 416 between the first and second planes 402ₙ, 402ₙ₊₁, read, write, erase, and independent plane functionality may be effectuated during use and operation of a microelectronic device including the microelectronic device structure 400.

Therefore, according to some embodiments, a microelectronic device may include a plane including blocks horizontally extending in parallel in a first direction and horizontally alternating with slot structures in a second direction orthogonal to the first direction. The blocks may respectively include tiers individually including conductive material and insulative material vertically neighboring the conductive material. The microelectronic device may further comprise an additional plane horizontally neighboring the plane in the second direction and including additional blocks horizontally extending in parallel in the first direction and horizontally alternating with additional slot structures in the second direction. The additional blocks may respectively include additional tiers individually including the conductive material and the insulative material vertically neighboring the conductive material. At least one source structure may vertically underlie and horizontally overlap horizontal areas of the plane and the additional plane. A plane separation region may be interposed between the plane and the additional plane in the second direction. The plane separation region may have a horizontal width in the second direction that is less than or equal to a combined horizontal width in the second direction of one of the blocks and two of the slot structures.

The microelectronic device structures 200, 300, 400 described herein may be fabricated using any suitable fabrication process. In some examples, the fabrication process may include a wafer-to-wafer bonding process in which an upper part and a lower part of the microelectronic device structure are fabricated separately and then bonded together. With such a fabrication process, metals such as copper may be employed in the source structure(s).

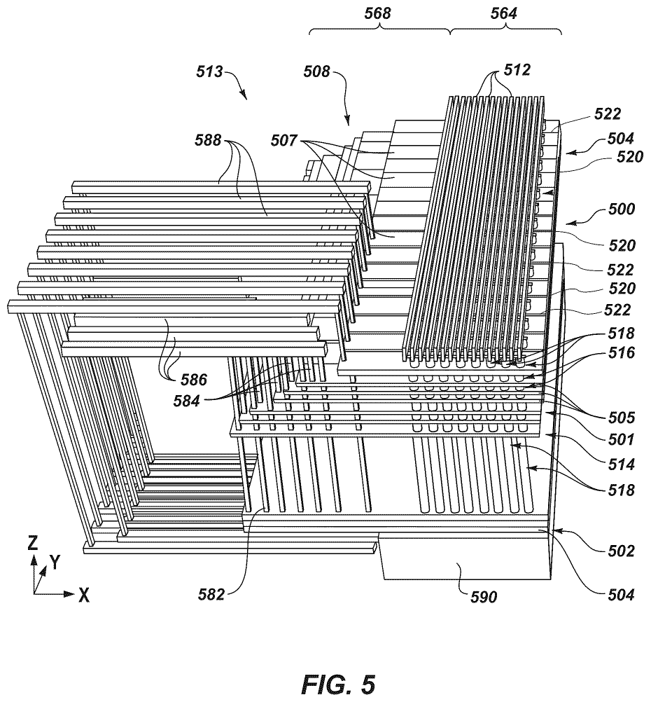

FIG. 5 illustrates a partial cutaway perspective view of a portion of a microelectronic device 513 (e.g., a memory device, such as a 3D NAND Flash memory device) including a microelectronic device structure 500. The microelectronic device structure 500 may be substantially similar to one of the microelectronic device structure 200 (FIGS. 2A and 2B), microelectronic device structure 300 (FIGS. 3A and 3B), and the microelectronic device structure 400 (FIGS. 4A and 4B). To avoid repetition, not all features (e.g., structures, materials, regions, devices) shown in FIG. 5 are described in detail herein. Rather, unless described otherwise below, in FIG. 5, a feature designated by a reference numeral that is a 100 increment of the reference numeral of a feature previously described with reference to one or more of FIG. 1A through FIG. 4B will be understood to be substantially similar to the previously described feature. In addition, for clarity and ease of understanding the drawings and associated description, some features of the microelectronic device structures 200, 300, 400 previously described with reference to FIGS. 2A-4B are not shown in FIG. 5. However, it will be understood that any features of the microelectronic device structure 200, 300, 400 previously described with reference to FIGS. 2A-4B may be included in the microelectronic device structure 500 of the microelectronic device 513 described herein with reference to FIG. 5.

As shown in FIG. 5, the blocks 504 may horizontally alternate with the slot structures 520 in the Y-direction, and may horizontally extend in parallel with one another in the X-direction orthogonal to the Y-direction. Furthermore, the blocks 504 may respectively include a memory array region 564, and a staircase region 568 horizontally neighboring the memory array region 564 in the X-direction. Within the memory array region 564, the blocks 504 may respectively include an array of cell pillar structures 518 (and, hence, an array of the vertically extending strings of memory cells 516). Within the staircase region 568, the blocks 504 may respectively include at least one staircase structure 508 having steps 507 defined by horizontal ends of the tiers 501 of the stack structure 514. Within an individual block 504, the steps 507 of the staircase structure 508 of the block 504 may serve as contact locations for the conductive material 505 of the tiers 501.

Still referring to FIG. 5, the microelectronic device 513 may further include bit lines 512 (e.g., data lines, digit lines), step contact structures 584, access line routing structures 586, and select line routing structures 588. The step contact structures 584 may contact (e.g., physically contact, electrically contact) the steps 507 of the staircase structures 508 within the staircase region 568 of the microelectronic device 513, and may couple components to one another as shown (e.g., the select line routing structures 588 to the conductive material 505 of some of the tiers 501 (e.g., upper ones of the tiers 501 separated by the additional slot structures 522) employed as upper select gates (e.g., SGDs); the access line routing structures 586 to the conductive material 505 of some others of the tiers 501 employed as local access lines). Additional contact structures 582 may vertically extend through the blocks 504 and may be employed as one or more of support structures and signal routing structures. In addition, as shown in FIG. 5, at least a portion of a base structure 590 is positioned within horizontal boundaries of the memory array regions 564 of the microelectronic device 513. The base structure 590 may include a control logic region including control logic circuitry (e.g., CMOS circuitry) that may be coupled to the vertically extending strings of memory cells 516. In such embodiments, the control logic region of the base structure 590 may be characterized as having a “CMOS under Array” (“CuA”) configuration.

Therefore, in some embodiments, a memory device includes a first plane including first blocks respectively comprising tiers each including conductive material and insulative material vertically neighboring the conductive material. The first plane also includes first strings of memory cells vertically extending through the first blocks. The memory device also includes a second plane including second blocks respectively comprising additional tiers each including the conductive material and the insulative material vertically neighboring the conductive material. The second plane also includes second strings of memory cells vertically extending through the second blocks. The memory device also includes at least one source structure vertically underlying the first plane and the second plane. The at least one source structure is coupled to the first strings of memory cells and the second strings of memory cells. A plane separation region horizontally extends from and between the first plane and the second plane in a first direction. The plane separation region has a width in the first direction less than a combined width in the first direction of two of the first blocks.

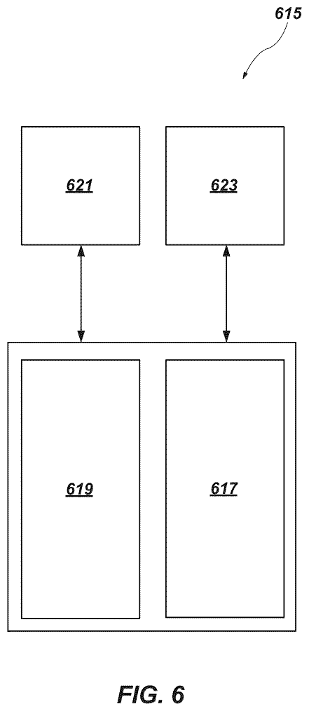

Microelectronic device structures (e.g., the microelectronic device structures 200, 300, 400 (FIGS. 2A-4B)) and microelectronic devices (e.g., the microelectronic device 513 (FIG. 5)) in accordance with embodiments of the disclosure may be used in embodiments of electronic systems of the disclosure. For example, FIG. 6 is a schematic block diagram of an illustrative electronic system 615 according to embodiments of disclosure. The electronic system 615 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 615 includes at least one memory device 617. The memory device 617 may include, for example, one or more of a microelectronic device structure (e.g., one of the microelectronic device structures 200, 300, 400 (FIGS. 2A-4B)) and a microelectronic device (e.g., the microelectronic device 513 (FIG. 5)) previously described herein. The electronic system 615 may further include at least one electronic signal processor device 619 (often referred to as a “microprocessor”). The electronic signal processor device 619 may, optionally, comprise one or more of a microelectronic device structure (e.g., the microelectronic device structures 200, 300, 400 (FIGS. 2A-4B)) and a microelectronic device (e.g., the microelectronic device 513 (FIG. 5)) previously described herein. While the memory device 617 and the electronic signal processor device 619 are depicted as two (2) separate devices in FIG. 6, in additional embodiments, a single (e.g., only one) memory/processor device having the functionalities of the memory device 617 and the electronic signal processor device 619 is included in the electronic system 615. In such embodiments, the memory/processor device may include one or more of a microelectronic device structure (e.g., one of the microelectronic device structures 200, 300, 400 (FIGS. 2A-4B)) and a microelectronic devices (e.g., the microelectronic device 513 (FIG. 5)) previously described herein.

The electronic system 615 may further include one or more input devices 621 for inputting information into the electronic system 615 by a user, such as, for example, a mouse or other pointing device, a keyboard, a touchpad, a button, or a control panel. The electronic system 615 may further include one or more output devices 623 for outputting information (e.g., visual or audio output) to a user such as, for example, a monitor, a display, a printer, an audio output jack, and/or a speaker. In some embodiments, the input device 621 and the output device 623 comprise a single touchscreen device that can be used both to input information to the electronic system 615 and to output visual information to a user. The input device 621 and the output device 623 may communicate electrically with one or more of the memory device 617 and the electronic signal processor device 619.

Therefore, according to some embodiments, an electronic system includes an input device, an output device, a processor device operably connected to the input device and the output device, and a memory device operably connected to the processor device. The memory device includes a plane including blocks horizontally separated by slot structures. The blocks respectively include tiers individually including conductive material and insulative material vertically neighboring the conductive material. Strings of memory cells vertically extend through the blocks. The memory device also includes an additional plane including additional blocks horizontally separated by additional slot structures. The additional blocks respectively include additional tiers individually including the conductive material and the insulative material vertically neighboring the conductive material. Additional strings of memory cells vertically extend through the additional blocks. At least one source structure vertically underlies the plane and the additional plane. The at least one source structure is coupled to the strings of memory cells and the additional strings of memory cells. A plane separation region is disposed between the plane and the additional plane. The plane separation region has a width that is less than a combined width of three of the blocks and four of the slot structures.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a plane comprising blocks horizontally extending in parallel in a first direction and horizontally alternating with slot structures in a second direction orthogonal to the first direction, the blocks respectively comprising tiers individually including conductive material and insulative material vertically neighboring the conductive material;
an additional plane horizontally neighboring the plane in the second direction and comprising additional blocks horizontally extending in parallel in the first direction and horizontally alternating with additional slot structures in the second direction, the additional blocks respectively comprising additional tiers individually including the conductive material and the insulative material vertically neighboring the conductive material;
at least one source structure vertically underlying and horizontally overlapping horizontal areas of the plane and the additional plane; and
a plane separation region interposed between the plane and the additional plane in the second direction, the plane separation region having a horizontal width in the second direction that is less than or equal to a combined horizontal width in the second direction of one of the blocks and two of the slot structures.

2. The microelectronic device of claim 1, wherein the at least one source structure comprises:
a first source structure vertically underlying and substantially continuously horizontally extending across the plane; and
a second source structure separate from the first source structure, the second source structure vertically underlying and substantially continuously horizontally extending across the additional plane.

3. The microelectronic device of claim 2, wherein:
the first source structure is substantially confined within a horizontal area of the plane; and
the second source structure is substantially confined within a horizontal area of the additional plane.

4. The microelectronic device of claim 2, wherein:
the first source structure partially horizontally extends, in the second direction, into the plane separation region; and
the second source structure partially horizontally extends, in the second direction, into the plane separation region.

5. The microelectronic device of claim 4, further comprising a further block within the plane separation region, the further block having a horizontal dimension, in the second direction, substantially equal to a horizontal dimension of the one of the blocks in the second direction.

6. The microelectronic device of claim 5, wherein portions of the first source structure and the second source structure horizontally overlap the further block in the second direction.

7. The microelectronic device of claim 1, wherein the at least one source structure comprises only one source structure vertically underlying and substantially continuous horizontally extending across each of the plane, the plane separation region, and the additional plane.

8. The microelectronic device of claim 1, wherein the horizontal width of the plane separation region is substantially equal to a horizontal width in the second direction of one of the slot structures.

9. The microelectronic device of claim 1, wherein the horizontal width of the plane separation region is substantially equal to the combined horizontal width in the second direction of the one of the blocks and the two of the slot structures.

10. The microelectronic device of claim 1, further comprising:
strings of memory cells within horizontal areas of and vertically extending through the blocks of the plane, the strings of memory cells coupled to the at least one source structure; and
additional strings of memory cells within horizontal areas of and vertically extending through the additional blocks of the additional plane, the additional strings of memory cells coupled to the at least one source structure.

11. The microelectronic device of claim 10, wherein the at least one source structure comprises:
a first source structure vertically underlying and coupled to the strings of memory cells; and
a second source structure electrically isolated from the first source structure, the second source structure vertically underlying and coupled to the additional strings of memory cells.

12. The microelectronic device of claim 10, wherein the at least one source structure comprises only one source structure vertically underlying and coupled to the strings of memory cells and the additional strings of memory cells.

13. A memory device, comprising:
a first plane comprising:
first blocks respectively comprising tiers each including conductive material and insulative material vertically neighboring the conductive material; and
first strings of memory cells vertically extending through the first blocks;
a second plane comprising:
second blocks respectively comprising additional tiers each including the conductive material and the insulative material vertically neighboring the conductive material; and
second strings of memory cells vertically extending through the second blocks;
at least one source structure vertically underlying the first plane and the second plane, the at least one source structure coupled to the first strings of memory cells and the second strings of memory cells; and
a plane separation region horizontally extending from and between the first plane and the second plane in a first direction, the plane separation region having a width in the first direction less than a combined width in the first direction of two of the first blocks.

14. The memory device of claim 13, wherein the at least one source structure comprises only one source structure substantially continuously horizontally extending in the first direction across and between each of the first plane and the second plane, the only one source structure coupled to the first strings of memory cells and the second strings of memory cells.

15. The memory device of claim 13, wherein the at least one source structure comprises:
a first source structure vertically underlying and horizontally overlapping the first plane, the first source structure coupled to the first strings of memory cells; and
a second source structure electrically isolated from the first source structure and vertically underlying and horizontally overlapping the second plane, the second source structure coupled to the second strings of memory cells.

16. The memory device of claim 15, further comprising an additional block within a horizontal area of the plane separation region, portions of the first source structure and the second source structure vertically underlying and horizontally overlap the additional block.

17. The memory device of claim 13, wherein the width in the first direction of the plane separation region is less than a width of one of the first blocks of the first plane.

18. The memory device of claim 13, wherein the width in the first direction of the plane separation region is substantially equal to a width of a slot structure horizontally extending in the first direction between two of the first blocks horizontally neighboring one another in the first direction.

19. An electronic system comprising:
an input device;
an output device;
a processor device operably connected to the input device and the output device; and
a memory device operably connected to the processor device and comprising:
a plane comprising:
blocks horizontally separated by slot structures, the blocks respectively comprising tiers individually including conductive material and insulative material vertically neighboring the conductive material;
strings of memory cells vertically extending through the blocks;
an additional plane comprising:
additional blocks horizontally separated by additional slot structures, the additional blocks respectively comprising additional tiers individually including the conductive material and the insulative material vertically neighboring the conductive material;
additional strings of memory cells vertically extending through the additional blocks;
at least one source structure vertically underlying the plane and the additional plane, the at least one source structure coupled to the strings of memory cells and the additional strings of memory cells; and
a plane separation region disposed between the plane and the additional plane, the plane separation region having a width that is less than a combined width of three of the blocks and four of the slot structures.

20. The electronic system of claim 19, wherein the memory device comprises a 3D NAND Flash memory device.
